(19) United States
(12) Patent Application Publication
(10) Pub. No.: US 2008/0041716 A1
(43) Pub. Date: Feb. 21, 2008

(54) Methods for producing photomask blanks, cluster tool apparatus for producing photomask blanks and the resulting photomask blanks from such methods and apparatus

(75) Inventors: Hakki Ufuk Alpay, Poughquag, NY (US); Devi Koty, Fishkill, NY (US); Michael Patrick Goudy, New Paltz, NY (US); Tit Keung Lau, Poughkeepsie, NY (US)

Correspondence Address: MILLEN, WHITE, ZELANO & BRANIGAN, P.C., 2200 CLARENDON BLVD., SUITE 1400, ARLINGTON, VA, 22201, US

(73) Assignee: Schott Lithotec USA Corporation

(21) Appl. No.: 11/505,985

(22) Filed: Aug. 18, 2006

(51) Int. Cl. C23C 14/32; C23C 14/00

(52) U.S. Cl. 204/192.2

(57) ABSTRACT

Described herein are photomask blanks and photomasks prepared therefrom, methods for producing the photomask blanks and apparatus used in such methods. In one aspect, there is described methods for preparing photomask blanks having layers with a compositional gradient, i.e., a varying composition through the thickness of the layer. In other aspects, either in conjunction with the above aspects or independently, methods and apparatus are provided which allow more efficient use of a cluster tool for preparing the photomask blanks and performing quality control on them. The inventions find applicability, for example, in preparing binary photomask blanks and phase shift photomask blanks.

The invention relates to photomask blanks and photomasks prepared therefrom, methods for producing the photomask blanks and apparatus used in such methods. In one aspect, more specifically, the invention relates to methods for preparing photomask blanks having layers with a compositional gradient, i.e., a varying composition through the thickness of the layer. In other aspects of the invention, either in conjunction with the above aspects or independently, methods and apparatus are provided which allow more efficient use of a cluster tool for preparing the photomask blanks and performing quality control on them. The inventions find applicability, for example, in preparing binary photomask blanks and phase shift photomask blanks.

In the production of semiconductor devices, such as integrated circuits, circuit patterns are formed on silicon wafers by optical or electron beam lithography. A photomask, comprising a patterned film on a substrate, serves as the circuit pattern template in the lithography process. Current trends in the semiconductor industry are towards increased circuit pattern density on the silicon wafers. As the circuit pattern density is increased, the permissible defect size and density on the photomask necessarily decrease. This decrease translates into fewer and smaller permissible defects in the photomask blank from which the photomask is formed.

A primary source of defects in photomask blanks is the blank manufacturing process. Conventional photomask blanks include two or more different masking layers on the transparent substrate. A light blocking layer, such as a chrome or chrome-based layer, and an antireflective layer, such as a chrome oxide layer, are the basic masking layers. Additional layers such as further antireflective layers, etch rate enhancing layers and adhesion promoting layers can also be used.

Typically, each masking layer is coated individually in separate coating operations. This is done, for example, in terms of a chrome and chrome oxide system, by sputtering a chrome layer on an uncoated substrate in a sputter chamber, then removing the chrome coated substrate from the chamber, altering the conditions in the chamber to create a chrome oxide sputtering atmosphere and then subjecting the chrome coated substrate to the new conditions. This type of process has some disadvantages. Between coating the different layers, the coating surface or sputtering chamber is susceptible to contamination. The contamination may be in the form of solid particulates created by mechanical removal and return of the substrate from and to the chamber, or solid residue, particles or dust remaining in the chamber from the previous sputtering conditions. Moreover, the contamination may also be gaseous should there by any back streaming of the vacuum pumping system between passes through the sputtering chamber.

Both forms of contamination reduce the adhesion at the coating interfaces in the final blank. Any adhesion loss, whether local or uniform, at any interface in the blank is a potential defect site in the final photomask. The rigorous processing steps of exposure, development, etching, stripping and numerous cleaning cycles, to which a blank is subjected in the manufacture of a photomask, enhance the likelihood that a given adhesion loss in a blank will generate a defect site in the photomask produced therefrom.

Another disadvantage of coating the masking layers in separate sputtering operations is the abrupt compositional interfaces between the layers. Such abrupt interfaces can suffer from brittleness and poor adhesion. In addition, the layers of different composition etch at different rates during formation of the circuit pattern in the film thereby creating defects such as antireflective layer overhang, and rough line edge profile, in the etched pattern.

Sputtering methods for providing photomask blanks with layers having a compositional gradient to, at least partially, avoid the drawbacks of a layer interface are known. See, e.g., U.S. Pat. Nos. 5,230,971 and 6,733,930, and Japan Published Application 02-242252 A2. Sputtering methods for providing layers with a compositional gradient for other applications, for example, in liquid crystal displays (LCD) or anti-reflections films, are also known; see, e.g., U.S. Pat. Nos. 5,922,181; 5,976,639; and 5,827,409; and US Pub. Appln. No. 2003/0201165.

Due to the cost of the raw materials used and the advanced facilities needed for methods of making photomasks, it is also desirable that the methods be as efficient as possible so that there is no waste of materials or facility time. Cluster tools for sputtering methods are known to provide some efficiency. These tools make use of multiple chambers for carrying out the several steps (such as load locks, vacuum sputtering chambers, transport chambers, inspection zones and zones for providing dummy substrates) and, generally, robotic mechanisms for transferring the substrate amongst the chambers. See, e.g., US Pub. Appln. No. 2004/0191651; U.S. Pat. Nos. 5,288,379; 5,925,227; 5,766,360; and 5,897,710; and Japan Published Application Nos. JP 2001-335927A2, JP 05-148633A2; JP 10-046331A2; JP 2001-335931A2; and JP 06-061326. However, more efficient methods for manufacturing photomasks are desired. Particularly, it would be desirable to get more efficient use out of dummy substrates so that they are used only as necessary and can be used more times before being discarded. Also, a more efficient inspection and quality control system is desirable. Additionally, more efficient handling of the mask blanks through load locks is desirable.

One aspect of this invention is a method for preparing photomask blanks having at least one layer with a compositional gradient, i.e., a varying composition through the thickness of the layer. The method comprises depositing a layer with a compositional gradient by sputtering in a single vacuum sputtering zone in the presence of plasma generated from at least one target, e.g., by applying electrical power to the target, wherein the composition of the plasma generated from the target is varied during the deposition of the layer, e.g., by varying the power applied to the target. The method can further comprise the use of additional targets of differing composition in the same sputtering zone and the additional targets are, optionally, also subject to variation in applied energy so that an additional gradient effect from such additional target(s) can be provided in the deposited layer. The method can further comprise providing at least one reactive gas in the same sputtering zone and, optionally, varying the composition of the reactive gas during the deposition of the layer to provide a further compositional gradient in a reactive gas element. The method allows for uninterrupted exposure of the photomask blank to the plasma during preparation, which: results in an efficient production rate, results in reducing opportunities for contamination and results in a gradual compositional change in the coating; all of which translate to fewer etch profile and spot defects in the final photomask. The method also uniquely results in providing layers which have a unique compositional gradient. By varying the energy provided to the target to achieve the compositional gradient, layers with a gradual change in composition and no abrupt interface can be provided using only one deposition process in a single deposition chamber.

FIG. 1 shows an Auger Electron Spectroscopy (AES) which provides an example of the type of unique gradient feature of the sputtered film that can be provided according to the invention. The AES method removes and analyzes already formed layers from the top down, thus, 0 sputter depth is the top of the layer. The component starting at about 60% in the top layer is oxygen, the component starting at about 25% in the top layer is chromium, the component starting at about 10% in the top layer is nitrogen, the component starting at about 0% in the top layer with the darker line is carbon and the component starting at about 0% in the top layer with lighter line is silicon.

The Auger Electron Spectroscopy (AES) in FIG. 1 shows atomic concentration carbon, oxygen, chromium, silicon and nitrogen as a function of surface and in-depth compositions of the sputtered film. Three regions of the film are pointed out: a) Anti-Reflection (AR) Layer as the top layer, b) Gradient Layer, c) Masking Layer as the bottom layer. Table 1 shows the process conditions range used for achieving this deposited layers with the three regions:

TABLE 1

| | Power on | | | |
|---|---|---|---|---|
| | Si/Cr target | Pressure | Gas concentration | Approximate |
| Film region | (W) | mT | N₂ %/O₂ %/C %/Ar % | Thickness, Å |
| AR Layer | 700 to 1200 | 0.5 to 1.5 | N₂ - 25–35%/O₂ - 40–50%/ | 150 |
| | | | C - 0–5%/Ar - 35–10% | |
| Gradient | Gradient | 0.5 to 1.5 | Gradually adjusted from | 250 |
| Layer | from bottom to | | that of bottom film to that | |
| | top film | | of top film | |
| Masking Layer | 1500 to 3000 | 0.5 to 1.5 | N₂ - 20–30%/O₂ - 25–35%/ | 600 |
| | | | C - 10–15%/Ar - 45–20% | |

Of course, this embodiment is only provided for exemplary purposes and the invention is not limited to this specific embodiment of a gradient layer. For example: different target materials can be used as described herein; different gases can be used as described herein; multiple targets with the same or different energy gradients applied thereto can be used; the rate of change in energy applied to the target(s) can be increased or decreased to modify the slope of the gradient for that material; preferably the gradient film has at least one metal component provided from a target wherein the film has a variation in atomic concentration of at least 10%, more preferably at least 20%, over the span of 1000 Å or less of film depth, preferably over the span of 500 Å or less of film depth; the energy gradient applied preferably increases from a minimum of 500 W, more preferably 800 W, or more to a maximum of 3000 W, more preferably 2000 W, or less or decreases from a maximum of 3000 W, more preferably 2000 W, or less to a minimum of 500 W, more preferably 800 W, or more; the rate of change in concentration of gases applied to the target(s) can be increased or decreased to modify the slope of the gradient for that material; preferably the gradient film has at least one component provided in the film from the gas atmosphere such that the film has a variation in atomic concentration of at least 10%, more preferably at least 20%, over the span of 1000 Å or less of film depth, preferably over the span of 500 Å or less of film depth; the total film thickness preferably ranges from 600 to 3,000 Å; and the film thickness of the gradient part of the film preferably ranges from 100 to 1000 Å, more preferably 200 to 500 Å.

Additionally, it is possible to provide the unique feature of a layer with elements deposited from the plasma and the elements deposited from the reactive gas both having a compositional gradient. The invention is directed to the described process and the unique products of the described process, e.g., photomask blanks and the resulting patterned photomasks which have at least one gradient as described herein and photomask blanks and the resulting patterned photomasks which have at least one layer which has both a compositional gradient in an element provided from a reactive gas and a compositional gradient in an element provided from plasma generated from a target. For example, the element(s) provided in a gradient from plasma generated from a target, can be a metal, or for short M, such as Cr, Mo, Zn, Co, Nb, W, Ti, Ta, W, Fe, Ni, In, Sn, Al, Mg or Si, or alloys or mixtures thereof. It is also possible to use oxides, carbides, sulfides, silicides, fluorides, and nitrides of these materials to provide the desired material in the layer(s). The element(s) provided from a reactive gas can be, for example, O, N, S, C, CO₂, CH₄, CF₄, CCl₄ or mixtures thereof. Examples of the resulting layers suited to the practice of this invention are metal oxy-carbo-nitrides (i.e., M-O—C—N), metal chloro-oxy-carbo-nitrides (i.e., M-Cl—O—C—N), metal chloro-fluoro-oxy-carbo-nitrides (i.e., M-Cl—F—O—C—N) and metal fluoro-oxy-carbo-nitrides (i.e., M-F—O—C—N) where M is selected from the above group of metals and mixtures thereof listed. Cr is a preferred M; and chromium oxy-carbonitride is a preferred material based upon performance and availability. Preferred embodiments of the combination of elements in the thus-prepared layer of the photomask blanks and the resulting patterned photomasks include providing both physical (optical properties) and chemical (compositional and wet etch) advantages to the product. Particular combinations of materials in the layer include: layers with chromium, silicon, carbon, oxygen and nitrogen; and layers with molybdenum and silicon optionally with carbon, oxygen, nitrogen, fluorine, and/or chlorine components.

Cluster tools for performing operations on substrates maintained under a vacuum are known, as discussed above. In general, the cluster tool operates to transfer, typically robotically, the substrates into and out of the one or more vacuum sputtering chambers, between sputtering chambers if there are multiple ones and into and out of various other processing step chambers without loss of the vacuum in the sputtering chamber. The cluster tool thus typically contains at least one load-lock chamber from which the substrate is introduced into the sputtering chamber and at least one load-lock chamber into which the sputtered substrate is passed out from the sputtering chamber. It is also typical for the cluster tool to have one or more separate inspection zone chambers wherein the substrate is passed to perform various types of quality control tests. The cluster tool will also have a robotic transferring mechanism within the tool for moving a substrate from one chamber to another and positioning it properly within the chamber. The robotic transferring mechanism is generally computer controlled and allows for quick and efficient operation while maintaining vacuum conditions and avoiding outside contamination.

It is also known to use dummy plates in connection with such cluster tools. It is known to use dummy plates, i.e., plates of similar size and shape to the photomask blank substrates but of inexpensive materials, to place in the sputtering chamber to gather deposited material when sputtering is conducted that is not desirable to prepare a useful photomask blank. For example, dummy plates are used as a base for depositing unwanted material from the sputtering chamber during start-up operations when the system has not yet achieved the desired steady state or is being tested to see if the desired steady state is being met. They can also be used for depositing undesired material during the cleaning of a target in the sputtering chamber. Targets can become contaminated on their surface due to reactive gases, particularly by oxides, used in the sputtering chamber or by outside contamination and, periodically, have to be cleaned by sputtering off their surface layer. Dummy plates are used to capture this unwanted material so that useful and more expensive substrates are not wasted. Further, dummy plates can be used multiple times to capture unwanted sputtered layers, however, at some point the dummy plate becomes over deposited or contaminated and has to be discarded.

Another aspect of the invention is a method and accompanying apparatus which makes more efficient use of dummy plates during sputtering using a cluster tool. According to this aspect of the invention, a separate vacuum chamber, e.g., a load-lock, in the cluster tool is provided for holding multiple dummy plates which has its own mechanism, typically robotic, for positioning a dummy plate in the sputtering zone during target cleaning operations. The mechanism is separate from that used for positioning the active substrates in the sputtering zone during active sputtering. In this way, contaminant on the target removed during the cleaning operations is not only avoided on the active substrates but is also avoided on the mechanism for positioning the active substrates. Avoiding contamination of the mechanism for positioning the active substrates provides an additional means for avoiding cross-contamination of the active substrates themselves. Further, maintaining the dummy plates in a vacuum chamber avoids additional contamination of the dummy plate. While the dummy plates are eventually discarded anyway, avoiding contamination on them lessens the possibility for transferring such contamination into the sputtering chamber during active sputtering. It also extends the useful life of the dummy plates, i.e., without additional material being deposited thereon due to contamination; the dummy plates can be used more times in target cleaning or start-up operations. Thus, the invention is directed to a method for producing photomask blanks in a cluster tool having a vacuum sputtering chamber wherein dummy plates are provided into the sputtering chamber from a vacuum chamber separate from that for the active substrates and using a mechanism separate from that used to transfer the active substrates into the sputtering chamber. Also, the invention is directed to a cluster tool apparatus comprising a vacuum sputtering chamber, a first transferring vacuum chamber for providing active substrates into the vacuum sputtering chamber, a robotic transferring mechanism for transferring active substrates from the first transferring vacuum chamber into the vacuum sputtering chamber, a second transferring vacuum chamber for providing pre-condition substrates into the vacuum sputtering chamber and a second robotic transferring mechanism for transferring dummy plates from the second transferring vacuum chamber into the vacuum sputtering chamber. FIG. 2 shows an example of a chamber configuration system according to an embodiment of the invention which includes an embodiment for locating the dummy plates within the system.

Another aspect of the invention is a method and accompanying apparatus, which provides for more efficient optical measurement of a property of sputtered substrates produced using a cluster tool. According to this aspect of the invention, at least one transferring area in communication with at least one load-lock chamber for unloading sputtered substrates from the sputtering chamber in the cluster tool is integrally provided with at least one optical measurement tool for providing a measurement of a property of the photomask blank being unloaded therein. The transferring area is the area between the sputtering chamber and the load-lock through which the substrates are passed when being unloaded from the sputtering chamber (see FIG. 2, for example). The transferring area is preferably within the same vacuum chamber wherein the sputtering is conducted but outside the active sputtering area. The optical measurement tool (exemplified by the OD “optical density” measuring device in FIG. 2) is provided integrally within the transferring area and not in a separate inspection zone chamber. The optical measurement tool(s) provided in the transferring area preferably includes, for example, one or more optical tool(s) for measuring optical density, reflectivity (e.g., by Reflectance Difference Spectroscopy, or Reflectance Anisotropy Spectroscopy), transmission, film thickness (e.g., calculation and modeling of n and k values), thickness uniformity (e.g., by elipsometry) or any other optically measurable property. Particularly, it is preferred that an optical tool for measuring optical density and/or reflectivity is provided integrally in the transferring area. In a preferred embodiment, the optical measurement(s) made in the transferring area are used for quality control to either accept or deny each photomask blank based on it exhibiting one or more threshold properties. In another preferred embodiment, the optical measurement tool is operated in a one point measurement manner, i.e., for efficiency purposes, only a single point, typically the middle of the substrate, is optically measured as being representative of the substrate as a whole. In another preferred embodiment, the optical measurement tool is provided by an optical fiber provided extending from the inside of the transferring area, through the wall of the device and leading to a means for measuring and processing the data of the optical signal received therefrom. Providing one or more optical measurement tool(s) in the transferring area makes the method and apparatus more efficient by eliminating the need for moving the photomask blank into a separate inspection zone. Thus, another opportunity for contamination is avoided and a processing efficiency of avoiding at least one transferring step to a separate inspection zone is eliminated. Instead, according to the invention, a substrate after sputtering can be measured for one or more properties with only a momentary pause as it transits from the sputtering chamber to the unloading load-lock. FIG. 3 shows a cross-sectional view of an embodiment of a device according to the invention having a tool for measuring both optical density and reflectivity by use of optical fibers provided integral with the transferring area in a vacuum transfer chamber. Therein, separate optical fibers for each measurement are provided extending into the transferring area above and below the center position of the sputtered substrate as it transits through the transferring area.

Thus, the invention is directed to a method for producing photomask blanks in a cluster tool having a vacuum sputtering chamber and an load-lock chamber for unloading sputtered substrates from the vacuum sputtering chamber, through a transferring area between the sputtering chamber and the load-lock, comprising conducting an optical measurement of a property of sputtered substrates within the transferring area by at least one optical measurement tool integrated in the transferring area. Also, the invention is directed to a cluster tool apparatus for producing photomask blanks which comprises a vacuum sputtering chamber, a load-lock chamber for unloading sputtered substrates from the vacuum sputtering chamber and a transferring area between the sputtering chamber and the load-lock, wherein the transferring area comprises, integrally therein, at least one optical measurement tool for measuring a property of a sputtered substrate within the transferring area.

Another aspect of the invention is a method and accompanying apparatus, which provides for more efficient movement of multiple blanks within a cluster tool. According to this aspect of the invention, a cassette is provided for holding multiple substrate/blanks and positioning them for supplying to the cluster tool operations chambers or collecting them from the cluster tool operations. Providing the cassette with multiple substrate/blanks makes the method and apparatus more efficient. The cassette can also be used advantageously to avoid or lessen contamination and/or damage of the substrates by use of a cassette having a unique assembly as exemplified in FIG. 4. The unique features of this advantageous embodiment of the cassette allow reduced contamination, reduced damage and/or increased throughput. The cassette preferably has a design, which avoids use of screws to assemble the cassette or similar small inaccessible areas. This allows more efficient cleaning of cassette and prevents cassette cleaning solution from seeping into screw holes or similar inaccessible areas. The cassette also preferably is constructed of materials and designed such that the part where the substrate contacts the cassette results in a minimum contact area with minimum wear or reduces substrate scratching. For example, the design is such that the part where the substrate contacts the cassette has a rounded shape and is constructed of a wear-resistant polymer material to avoid potential contamination or damage to the substrate. As exemplified by FIG. 4, this embodiment of the cassette provides slots defined by corresponding donut-shaped protrusions on each of 4 rods along the side corners of the cassette. The substrates rest only on minimal contact points of each of 4 horizontally-corresponding donut-shaped protrusions, i.e., one from each rod a the same horizontal plane. Thus, there is a minimal surface of contact of the substrate which minimizes the potential for wear or scratching. Additionally, the donut-shaped protrusions are made of, or coated by, a material which is resistant to scratching or otherwise wearing on the substrate. The rod carrying the protrusions can also be made of, or coated by, such material. The material is a non-abrasive polymer material which is rigid enough to support the structure for multiple uses but flexible enough to minimize impact on the substrates. Suitable materials include, for example, polyetheretherketone (PEEK) resins, or other materials similarly offering high strength, good chemical resistance so as to avoid contamination, and good dimensional stability such that its properties are maintained when subject to a vacuum. In FIG. 4, the cassette assembly is put together without screws or similar connectors to avoid tight areas susceptible to collect contamination. Instead, it is seen in this embodiment that the rods are press fit into slots and holes in the top and bottom plates of the cassette. In operation, the entire cassette with substrates is loaded into the load-lock and subject to a vacuum in order to be in position to provide the multiple cassettes into the sputter chamber.

Thus, the invention is additionally directed to a novel cassette for multiple blanks which has the feature(s) of the cassette described above. Thus, the invention is also directed to a method for producing photomask blanks in a cluster tool having a vacuum sputtering chamber wherein the substrates are provided to the load-lock using such a cassette. Also, the invention is directed to a cluster tool apparatus for producing photomask blanks which comprises a vacuum sputtering chamber and a cassette having such arrangement.

In the methods of producing photomask blanks described above, any substrates suitable for this purpose, including those known in the art, may be used. For example, known substrates comprising glass, such as fused silica (or quartz) may be used. A conductive and semi or non-transparent layers are sputter deposited, for example by known methods, in metallic form or as a combination of oxides, nitrides and silicides, fluorides, of the metal or for short M such as Cr, Mo, Zn, Co, Nb, W, Ti, Ta, W, Fe, Ni, In, Sn, Al, Mg or Si, or alloys or mixtures thereof and the like, may cover at least one surface of the substrate. The substrate must be transparent to light in the wavelength region of the lithography process in which the final photomask product will be used. This wavelength region is preferably in the range of 190 to 900 nanometers, most often in the 350 to 600 nanometer range. The masking layer is deposited on the substrate by reactive sputtering. Reactive sputtering is a coating process that takes place in a vacuum chamber. Within the vacuum chamber is a sputter chamber filled with a gas comprising inert gas and reactive gas under a predetermined pressure. A target comprising the material to be sputtered is positioned in the sputter chamber on an electrically conductive cathode. As a negative electrical potential is applied to the target, plasma extending from the surface of the target is formed. The plasma comprises inert and reactive gas ions and reactive radicals. As the sputtered atoms travel through the plasma, they react with the reactive gas species therein to form various compounds. The compounds are deposited in a thin film or layer format on the substrate as it moves through the sputter chamber. Inert gases suitable for this process include argon and xenon. Suitable reactive gases include nitrogen, oxygen, methane, and carbon dioxide. Pressure in the sputter chamber is usually in the range of 0.3 mTorr to 9.0 mTorr. Examples of the materials used for the target are described above. Multiple targets may be used and they may have different compositions in order to provide a mixed plasma for depositing.

The conditions as described herein are preferably optimized to facilitate the seamless marrying of the layers of materials (e.g., masking layer and anti-reflection layer with seamless gradient layer there between) in a process that can be continuously carried out, i.e., each substrate is subjected to a seamless sputtering process.

The invention is applicable, for example, for preparing binary photomask blanks and phase shift photomask blanks which are defect free and achieve target critical dimension performance in wet/dry etch conditions, i.e., the blanks and masks made therefrom advantageously achieve the desired sharp pattern features which are desired, for example, in EUV, I-Line, or G-line lithography.

Exemplary embodiments of the invention include the following:

a. A method for preparing a photomask blank which comprises depositing a layer with a compositional gradient on a substrate by sputtering in a single vacuum sputtering zone in the presence of plasma generated from at least one target wherein the composition of the plasma generated from the target is gradually varied during the deposition of the layer.
b. The above method wherein the composition of the plasma generated from the target is varied by varying the power applied to the target.
c. One of the above methods further comprising generating plasma from at least one further target of differing composition in the same sputtering zone.
d. The above method c. wherein at least one further target is also subject to variation in applied energy so that an additional gradient effect in the deposited layer from such additional target is achieved.
e. One of the above methods further comprising providing at least one reactive gas in the same sputtering zone.
f. The above method e. wherein the composition of the reactive gas is varied during the deposition of the layer to provide a further compositional gradient in one or more deposited reactive gas elements.
g. A method for producing photomask blanks in a cluster tool having a vacuum sputtering chamber, a first vacuum chamber for active substrates and a mechanism for transferring active substrates from the first vacuum chamber for active substrates to the vacuum sputtering chamber, wherein at least one dummy plate is provided into the sputtering chamber from a vacuum chamber separate from the vacuum chamber for active substrates and using a mechanism for transferring the dummy plate that is separate from the mechanism used to transfer the active substrates into the sputtering chamber.
h. A photomask or photomask blank having at least one single layer which has both a compositional gradient in an element provided from a reactive gas and a compositional gradient in an element provided from plasma generated from a target.
i. A photomask or photomask blank having an anti-reflection layer and a masking layer and a gradient layer therebetween which has a compositional gradient in an element gradually varying from its composition in the anti-reflection layer to its composition in the masking layer, wherein the element is provided from a reactive gas and/or from plasma generated from a target.
j. A cluster tool apparatus comprising a vacuum sputtering chamber, a first transferring vacuum chamber for providing active substrates into the vacuum sputtering chamber, a robotic transferring mechanism for transferring active substrates from the first transferring vacuum chamber into the vacuum sputtering chamber, a second transferring vacuum chamber for providing dummy plates into the vacuum sputtering chamber and a second robotic transferring mechanism for transferring dummy plates from the second transferring vacuum chamber into the vacuum sputtering chamber.
k. A method for producing photomask blanks in a cluster tool having a vacuum sputtering chamber, a load-lock chamber for unloading sputtered substrates from the vacuum sputtering chamber and a transferring area between the vacuum sputtering chamber and load-lock chamber, comprising conducting an optical measurement of a property of a sputtered substrate within the transferring area by an optical measurement tool integrated in the transferring area.
l. A cluster tool apparatus for producing photomask blanks which comprises a vacuum sputtering chamber and an unload chamber for unloading sputtered substrates from the vacuum sputtering chamber wherein the unload chamber comprises, integrally therein, at least one optical measurement tool for measuring a property of a sputtered substrate within the unload chamber.
m. A method for producing photomask blanks in a cluster tool having a vacuum sputtering chamber wherein the substrates are provided to the load-lock from a cassette which can hold multiple photomask blank substrates as shown in FIG. 4 above.
n. A method as in a. above which is used to manufacture binary and nanoimprint photomask blanks in thickness ranging from 5 Å to 3000 Å, and the resulting photomask blanks.
o. A method as in a. above which is used to manufacture transmissive embedded phase shift photomask blanks wherein the phase shift is 180 degrees, and the resulting phase shift photomask blanks.
p. The method of o. above which is used to make transmissive embedded phase shift photomask blanks having a transmission varying from 0.1 to 0.9 at lithographic wavelength.
q. The method of o. above which is used to make transmissive embedded phase shifter-photomask blanks wherein the reflectance is within the range of from 0 to 0.5 at lithographic wavelength.

While the invention has thus far been described in conjunction with some embodiments thereof, it is to be understood that those skilled in the art may practice the invention in various ways. For example, various combinations of targets and gas mixtures may be employed.

The entire disclosure of all applications, patents and publications, cited herein is incorporated by reference herein.

### BRIEF DESCRIPTION OF THE DRAWINGS

FIG. 1 is Example of embodiment according to the invention having unique gradient feature of the film.

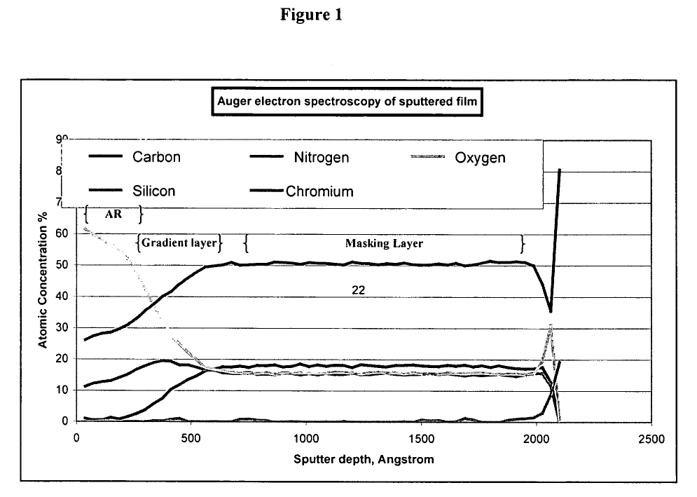

FIG. 2 is Example of Chamber Configuration according to an embodiment of the invention.

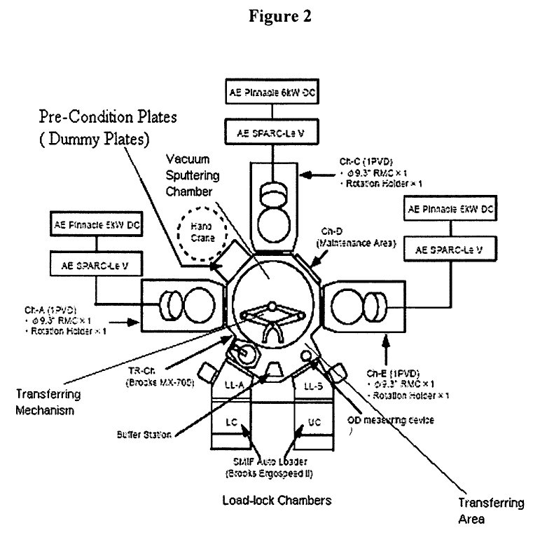

FIG. 3 is Cross-section view of an example of optical measurement device integral to transferring area of vacuum transfer chamber

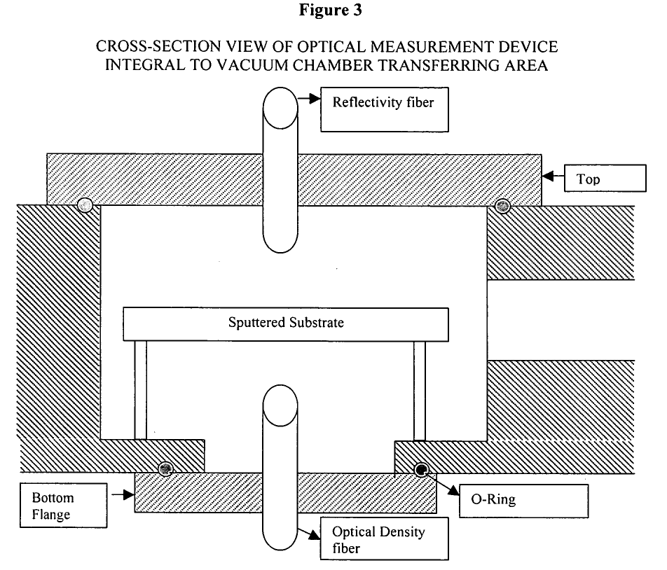

FIG. 4 is Isometric view of multi-substrate cassette

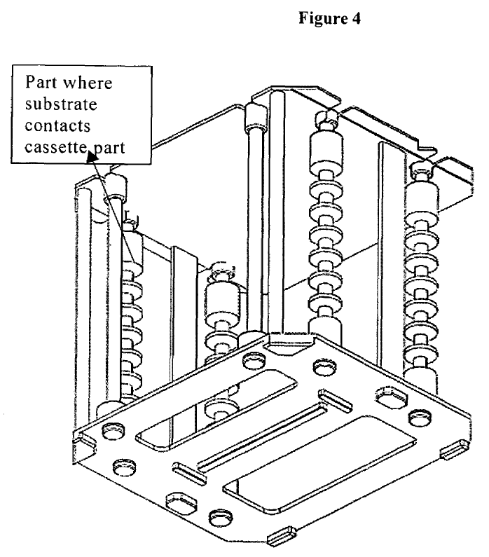

### Tables:

Table 1—Process values range of deposited films

Without further elaboration, it is believed that one skilled in the art can, using the preceding description, utilize the present invention to its fullest extent. The specific embodiments described herein are, therefore, to be construed as merely illustrative, and not limitative of the disclosure in any way whatsoever. From the foregoing description, one skilled in the art can easily ascertain the essential characteristics of this invention and, without departing from the spirit and scope thereof, can make various changes and modifications of the invention to adapt it to various usages and conditions.

1. A method for preparing a photomask blank which comprises depositing a layer with a compositional gradient on a substrate by sputtering in a single vacuum sputtering zone in the presence of plasma generated from at least one target, wherein:
the composition of the plasma generated from at least one target is gradually varied during the deposition of the layer, and/or
at least one reactive gas is provided in the same sputtering zone and the composition of the reactive gas is gradually varied during the deposition of the layer,
such that the deposited layer has a compositional gradient in at least one component.

2. The method of claim 1 wherein the composition of the plasma generated from at least one target is gradually varied during the deposition of the layer.

3. The method of claim 2, wherein the composition of the plasma generated from the target is varied by varying the power applied to the target.

4. The method of claim 2, wherein at least one further target of differing composition is provided in the same sputtering zone and sputtering is also conducted on such further target.

5. The method of claim 4, wherein the at least one further target is also subject to variation in applied energy so that an additional gradient effect in the deposited layer from such additional target is achieved.

6. The method of claim 2, wherein there is at least one reactive gas in the same sputtering zone.

7. The method of claim 1, wherein the composition of the reactive gas is varied during the deposition of the layer to provide a compositional gradient in one or more deposited reactive gas elements.

8. The method of claim 2, wherein the composition of the reactive gas is varied during the deposition of the layer to provide a further compositional gradient in one or more deposited reactive gas elements.

9. The method of claim 1, wherein the resulting photomask blank is a binary and nanoimprint photomask blank having a thickness ranging from 5 Å to 3000 Å.

10. The method of claim 1, wherein the photomask blank is a transmissive embedded phase shift photomask blank wherein the phase shift is 180 degrees.

11. The method of claim 10, wherein the transmissive embedded phase shift photomask blank has a transmission varying from 0.1 to 0.9 at lithographic wavelength.

12. The method of claim 10, wherein the transmissive embedded phase shift photomask blank has a reflectance within the range of from 0 to 0.5 at lithographic wavelength.

13. The method of claim 2, wherein the plasma is continuously generated while the composition of the plasma generated from at least one target is gradually varied during the sputtering and deposition of the layer.

14. A photomask or photomask blank having at least one single layer which has both a compositional gradient in an element provided from a reactive gas and a compositional gradient in an element provided from plasma generated from a target.

15. A photomask or photomask blank having an anti-reflection layer and a masking layer and a gradient layer therebetween which has a compositional gradient in an element gradually varying from its composition in the anti-reflection layer to its composition in the masking layer, wherein the element is provided from a reactive gas and/or from plasma generated from a target.

16. A method for producing photomask blanks in a cluster tool having a vacuum sputtering chamber, a first vacuum chamber for active substrates and a mechanism for transferring active substrates from the first vacuum chamber for active substrates to the vacuum sputtering chamber, wherein at least one dummy plate is provided into the sputtering chamber from a vacuum chamber separate from the vacuum chamber for active substrates and using a mechanism for transferring the dummy plate that is separate from the mechanism used to transfer the active substrates into the sputtering chamber.

17. A cluster tool apparatus comprising a vacuum sputtering chamber, a first transferring vacuum chamber for providing active substrates into the vacuum sputtering chamber, a robotic transferring mechanism for transferring active substrates from the first transferring vacuum chamber into the vacuum sputtering chamber, a second transferring vacuum chamber for providing dummy plates into the vacuum sputtering chamber and a second robotic transferring mechanism for transferring dummy plates from the second transferring vacuum chamber into the vacuum sputtering chamber.

18. A method for producing photomask blanks in a cluster tool having a vacuum sputtering chamber, a load-lock chamber for unloading sputtered substrates from the vacuum sputtering chamber and a transferring area between the vacuum sputtering chamber and load-lock chamber, comprising conducting an optical measurement of a property of a sputtered substrate within the transferring area by an optical measurement tool integrated in the transferring area.

19. A cluster tool apparatus for producing photomask blanks which comprises a vacuum sputtering chamber and an unload chamber for unloading sputtered substrates from the vacuum sputtering chamber wherein the unload chamber comprises, integrally therein, at least one optical measurement tool for measuring a property of a sputtered substrate within the unload chamber.

20. A cassette which can hold multiple photomask blank substrates or coated substrate blanks usable in connection with a vacuum sputtering zone to prepare photomask blanks from such substrates, wherein the cassette:
comprises means for holding multiple substrates or resulting blanks and positioning them for supplying to the sputtering zone and/or collecting them from the sputtering zone;
has a design for reduced contamination, reduced damage and/or increased throughput in producing photomask blanks, which design avoids use of screws to assemble the cassette or similar small inaccessible areas susceptible to contamination; and
is constructed of materials and designed such that the part where the substrate contacts the cassette results in a minimum contact area with minimum wear and/or reduces substrate scratching of the substrate or substrate blank.

21. The cassette of claim 20, wherein:
the cassette comprises a top and bottom plate and four rods therebetween to define a rectilinear volume wherein the rods are press fit into slots and holes in the top and bottom plates without screws or similar fasteners;
the cassette further comprises slots defined by corresponding donut-shaped protrusions on each of the four rods along the side corners of the cassette such that an inserted substrate or blank rests only on minimal contact points of each of four horizontally-corresponding donut-shaped protrusions and
wherein the part of the cassette where the substrate or blank contacts the cassette has a rounded shape and is constructed of a wear-resistant polymer material which is resistant to scratching or otherwise wearing on the substrate or blank.

22. A method for producing photomask blanks in a cluster tool having a vacuum sputtering chamber wherein the substrates are provided to the load-lock from a cassette according to claim 20.
